(19) United States
(12) Patent Application Publication
(10) Pub. No.: US 2010/0251043 A1
(43) Pub. Date: Sep. 30, 2010

(54) SEMICONDUCTOR INTEGRATED CIRCUIT, CIRCUIT FUNCTION VERYFICATION DEVICE AND METHOD OF VERYFYING CIRCUIT FUNCTION

(75) Inventors: Kenichi Anzou, Kawasaki-shi (JP); Chikako Tokunaga, Yokohama-shi (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/721,768

(22) Filed: Mar. 11, 2010

(30) Foreign Application Priority Data
Mar. 24, 2009 (JP) 2009-71871

(51) Int. Cl. G11C 29/04; G06F 11/22

(52) U.S. Cl. 714/719; 714/E11.145

(57) ABSTRACT

A semiconductor integrated circuit has a data generation circuit configured to generate first data used for function verification of a built-in self test circuit and a built-in redundancy allocation circuit of a memory, a failure data generation circuit configured to generate second data for conducting a built in self test by inverting at least one bit of the first data based on a failure injection indication signal, and a timing circuit configured to adjust timing of at least one of the first and the second data in order to use one of the first and the second data as writing data to the memory and to use the other as an output expected value compared with data read out from the memory.

### CROSS REFERENCE TO RELATED APPLICATIONS

This application is based upon and claims the benefit of priority from the prior Japanese Patent Applications No. 2009-71871 filed on Mar. 24, 2009, the entire contents of which are incorporated herein by reference.

### BACKGROUND OF THE INVENTION

1. Field of the Invention

The present invention relates to a semiconductor integrated circuit for conducting a self-test of a memory, a circuit function verification device and a method of verifying circuit function.

2. Related Art

In general, a pass/fail determination circuit and a repair analysis circuit are integrated in a semiconductor integrated circuit and a pass/fail determination and a redundancy analysis of a memory device are performed at the time of fabrication. A circuit for generating various types of signals for conducting the pass/fail determination and the redundancy analysis are called a built-in self test (hereinafter, referred to as MST) circuit and a built-in redundancy allocation (hereinafter, referred to as BIRA) circuit.

For example, the pass/fail determination circuit performs the pass/fail determination that determines whether there are failure bits in the memory. The repair analysis circuit analyzes which part of spare elements is to be replaced to the failure bits to repair the memory based on the result of the memory output analysis. That is, the repair analysis circuit performs a processing for finding out a repair solution. Based on the repair solution, it is possible to replace a part of the memory including the failure bits which cannot be normally written or read out with the spare memory. Therefore, the memory including the failure bits can be made shipment as a nondefective one, thereby improving a fabrication yield.

Function verification of the pass/fail determination and the repair analysis in a practical device is so difficult. This is because the function verification cannot be performed when there are no failure bits in the memory. A first option for the function verification is to prepare memories having the failure bits and verify using these memories including the failure bits. However, it is not easy to prepare the necessary and sufficient number of memories for the function verification. In particular, as the capacity of the memory becomes larger, the number of memories necessary for the function verification also increases. A second option for the function verification is to generate the failure bits physically by using a certain equipment such as focused ion beam in order to inject the failure bits. However, the second option is not practical because the cost of the function verification increases.

Because of the above circumstances, it may be necessary to adopt a simplified technique for injecting the failure bits to the memory.

US2001/52090 discloses a technique to perform function verification of a circuit for performing an error correction of data written in a memory. However, the publication does not take injection of the failure bits into consideration, and does not assume the pass/fail determination and the repair analysis.

### SUMMARY

According to one aspect of the present invention, a semiconductor integrated circuit comprising: a data generation circuit configured to generate first data used for function verification of a built-in self test circuit and a built-in redundancy allocation circuit of a memory; a failure data generation circuit configured to generate second data for conducting a built in self test by inverting at least one bit of the first data based on a failure injection indication signal; and a timing circuit configured to adjust timing of at least one of the first and the second data in order to use one of the first and the second data as writing data to the memory and to use the other as an output expected value compared with data read out from the memory.

According to the other aspect of the present invention, a circuit function verification device comprising: a data generation circuit configured to generate first data used for function verification of a built-in self test circuit and a built-in redundancy allocation circuit of a memory having a redundancy part; a failure data generation circuit configured to generate second data for conducting a built in self test by inverting at least one bit of the first data based on a failure injection indication signal; a timing circuit configured to adjust timing of at least one of the first and the second data in order to use one of the first and the second data as writing data to the memory and to use the other as an output expected value compared with data read out from the memory; a comparison circuit configured to read out data written in the memory to compare the read-out data with the output expected value; and a pass/fail determination circuit configured to determine whether at least one failure bit is present in the memory based on a comparison result of the comparison circuit.

According to the other aspect of the present invention, a method of verifying circuit function comprising: generating first data used for function verification of a built-in self test circuit and a built-in redundancy allocation circuit of a memory having a redundancy part; generating second data for conducting a built in self test by inverting at least one bit of the first data based on a failure injection indication signal by a failure data generation circuit; adjusting timing of at least one of the first and the second data in order to use one of the first and the second data as writing data to the memory and to use the other as an output expected value compared with data read out from the memory; reading out data written in the memory to compare the read-out data with the output expected value; and determining whether at least one failure bit is present in the memory based on a comparison result.

### BRIEF DESCRIPTION OF THE DRAWINGS

FIG. 1 is a block diagram showing a schematic configuration of a semiconductor integrated circuit according to a first embodiment of the present invention.

FIG. 2 is a block diagram showing an example of an internal configuration of a BIST circuit 1.

FIG. 3 is a flowchart showing a sequence of performing the function verification of a pass/fail determination.

FIGS. 4(A) and 4(B) are block diagrams showing modification examples of the BIST circuit 1 of FIG. 2.

FIG. 5 is a block diagram showing an example of an internal configuration of a BIST circuit 1c according to a second embodiment of the present invention.

FIG. 6 is a block diagram showing a schematic configuration of a circuit for verifying function of a BWE.

FIG. 7 is a flowchart showing a sequence of performing a function verification of the BWE using a test circuit of FIG. 6.

FIG. 8 is a block diagram showing an example of an internal configuration of a BIST circuit 1d according to a third embodiment of the present invention.

FIG. 9 is a schematic configuration of a semiconductor integrated circuit according to a fourth embodiment of the present invention.

FIG. 10 is a flowchart showing a sequence of the repair processing of a memory 2.

FIG. 11 is a flowchart showing a sequence of the function verification of the repair processing of FIG. 10.

### DETAILED DESCRIPTION OF THE INVENTION

Hereinafter, a semiconductor integrated circuit, a circuit function verification device and a method of verifying circuit function according to embodiments of the present invention will be specifically explained with reference to accompanying drawings.

### First Embodiment

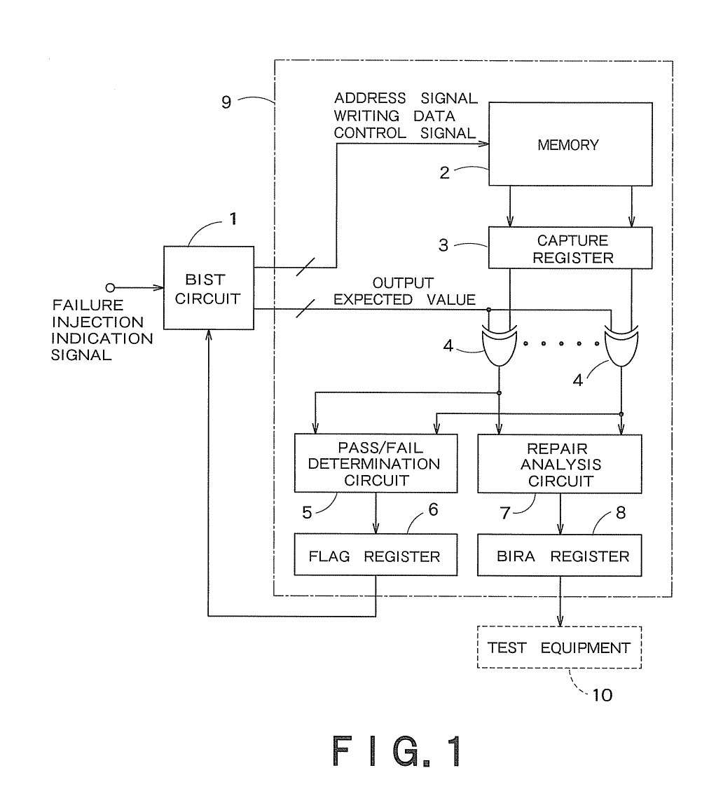

FIG. 1 is a block diagram showing a schematic configuration of a semiconductor integrated circuit according to a first embodiment of the present invention. The semiconductor integrated circuit of FIG. 1 has a BIST circuit 1, a memory 2, a capture register 3, comparison circuits 4, the number of which is the same as that of the bits of input/output data of the memory 2, a pass/fail determination circuit 5, a flag register 6, a repair analysis circuit 7, and a BIRA register 8. The components except the BIST circuit 1 are integrated in a memory collar 9.

The BIST circuit 1 and the memory collar 9 can be integrated in a chip or can be composed of different chips. The memory 2 is, for example, a DRAM (Dynamic Random Access Memory), an SRAM (Static Random Access Memory), or a Flash memory. However, the type of the memory is not especially limited.

The present embodiment proposes an example for performing function verifications of a pass/fail determination and a repair analysis using the BIST circuit 1. Here, the accompanying drawings, if not mentioned in particular, illustrate only signal paths necessary for the function verifications of the pass/fail determination and the repair analysis of the memory 2, and omit signal paths used under normal operation of the memory 2.

The BIST circuit 1 generates an address signal, writing data, a control signal and an output expected value, which will be explained below. The BIST circuit 1 generates an address signal, and control signal to read out data from the memory 2 and the capture register 3 temporally holds the read-out data. Each of the comparison circuits 4 compares the read-out data from the memory 2 with the output expected value by each bit to determine whether the read-out data from the memory 2 coincides with the output expected value. FIG. 1 shows an example where the comparison circuit 4 is composed of an exclusive OR (EXOR) circuit. However, the specific circuit configuration of the comparison circuit 4 is not limited. Each of the comparison circuits 4 compares the read-out data from the memory 2 with the output expected value and outputs a value of “0” when they coincide, while each outputs a value of “1” when they do not coincide by bit.

The memory 2 has a spare elements (not shown) therein and has a repair function using the spare elements for repairing failure bits.

The pass/fail determination circuit 5 determines whether the memory 2 has the failure bits based on output signals of the comparison circuits 4. The pass/fail determination circuit 5 outputs the value of “1” when the memory 2 has the failure bits, while it outputs the value of “0” when the memory 2 does not have the failure bits. The flag register 6 temporally holds the determination result to output the determination result to the BIST circuit 1 or to a test equipment (not shown) provided outside of the semiconductor integrated circuit.

Based on the output signals of the comparison circuits 4, the repair analysis circuit 7 analyzes whether repair can be performed, and when the repair can be performed, the repair analysis circuit 7 analyzes which part of the spare memory to replace to the failure bits. The BIRA register 8 temporally holds the analysis result (repair solution) to output to the test equipment (not shown) provided outside of the semiconductor integrated circuit.

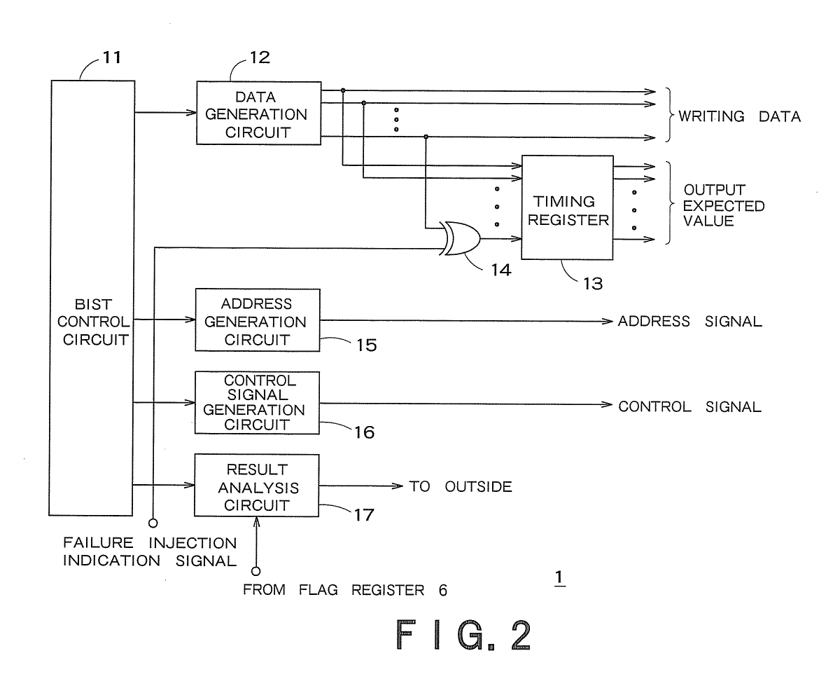

FIG. 2 is a block diagram showing an example of an internal configuration of the BIST circuit 1. The BIST circuit 1 has a BIST control circuit 11, a data generation circuit 12, a timing register 13, a bit inversion circuit 14, an address generation circuit 15, a control signal generation circuit 16, and a result analysis circuit 17.

The BIST control circuit 11 controls the data generation circuit 12, the address generation circuit 15, and the result analysis circuit 17. The data generation circuit 12 generates the writing data.

The bit inversion circuit 14 sets one of bitlines of the memory 2 to be in a failure state according to a failure injection indication signal. FIG. 2 shows an example where the bit inversion circuit 14 is composed of an EXOR circuit. However, the specific circuit configuration of the bit inversion circuit 14 is not limited. The bit inversion circuit 14 calculates the exclusive OR between the failure injection indication signal and one bit of its output expected value.

Here, the failure injection indication signal is a signal which is inputted from outside of the BIST circuit 1 and sets one of the bitlines of the memory 2 to be in the failure state in appearance. When the failure injection indication signal is the value of “0”, the bit inversion circuit 14 does not invert the output expected value. This corresponds to state where no failure bits are present. Contrarily, when the failure injection indication signal is the value of “1”, the bit inversion circuit 14 inverts the output expected value. This corresponds to a state where the failure bit is injected. That is, when the output expected value is inverted, the output expected value coincides with the writing data, thereby virtually implementing a state where the memory 2 fails.

As mentioned above, the failure injection indication signal in the present embodiment does not intend to set a specific cell of the memory 2 to be in the failure state, but intends to set a specific bitline of the memory 2 to be in the failure state.

The failure injection indication signal can be inputted from outside of the semiconductor integrated circuit in which the BIST circuit 1 is integrated or can be inputted from other circuit such as a test mode control circuit (not shown) integrated in the same semiconductor integrated circuit.

The bit inversion circuit 14 is connected to only a specific bit of the writing data composed of multiple bits. That is, the present embodiment assumes that the function verification of the pass/fail determination is performed with respect to one failure of the bitlines of the memory 2. Any bit can be connected to the bit inversion circuit 14.

The timing register 13 once holds the writing data and the output signal of the bit inversion circuit 14 and then outputs the writing data and the output signal as the output expected value. Therefore, output timing of the expected value is adjusted by delaying the writing data and the output signal of the bit inversion circuit 14 for a time depending on read/write time of the memory 2. More specifically, the timing register 13 adjusts the output timing so that the comparison circuit 4 can surely compare data which is written in the memory 2, and then read out from the memory 2, and then inputted to the comparison circuit 4 through the capture register 3, with the output expected value.

The address generation circuit 15 generates an address signal for reading from or writing to the memory 2. The control signal generation circuit 16 generates a control signal for controlling operations of reading from and writing to the memory 2.

The result analysis circuit 17 determines whether the memory 2 is defective based on an output signal of the flag register 6 in the memory collar 9. When there are multiple memories 2 to be tested, the repair analysis circuit 17 determines whether each of the memories is defective based on the output signal of each of the flag registers 6. Furthermore, the result analysis circuit 17 outputs the determination result to the outside test equipment.

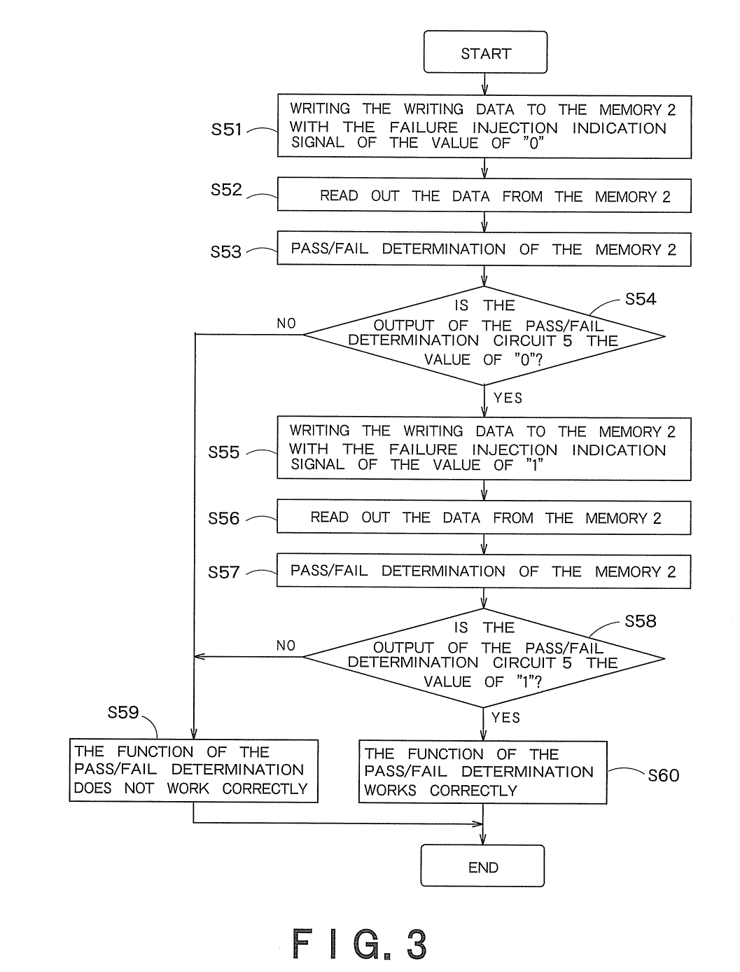

FIG. 3 is a flowchart showing a sequence of performing the function verification of the pass/fail determination. The processing operation for performing the function verification of the pass/fail determination using the BIST circuit 1 of FIG. 1 and FIG. 2 will be explained.

Firstly, the failure injection indication signal is set to be the value of “0”, and the BIST circuit 1 writes the writing data to the memory 2 in a state where no failure is present in the memory 2 (Step S51). Here, the writing data is arbitrary. Next, the BIST circuit 1 reads out the data written in the memory 2 (Step S52). The read-out data is inputted to the comparison circuit 4 through the capture register 3. The comparison circuit 4 outputs the result of comparing the read-out data from the memory 2 with the output expected value generated by the BIST circuit 1.

The pass/fail determination circuit 5 performs the pass/fail determination based on the output signal of the comparison circuit 4 (Step S53). The determination result is inputted to the result analysis circuit 17 in the BIST circuit 1 through the flag register 6. In Steps S51 and S52, the writing and reading operations are performed in the state where no failure bits are present in the memory 2. Therefore, the pass/fail determination circuit 5 should output the value of “0” indicating that no failure bits are present in the memory 2. Accordingly, when the pass/fail determination circuit 5 outputs the value of “1” (Step S54), the result analysis circuit 17 determines that the function of the pass/fail determination does not work correctly (Step S59).

Then, the failure injection indication signal is set to be the value of “1”, and the BIST circuit 1 writes the writing data to the memory 2 in the state where the failure is present in one of the bitlines of the memory 2 (Step S55). The writing data is arbitrary. Next, the BIST circuit 1 reads out the data written in the memory 2 (Step S56). The read-out data is inputted to the comparison circuit 4 through the capture register 3. The comparison circuit 4 outputs the result of comparing the read-out data from the memory 2 with the output expected value generated by the BIST circuit 1.

The pass/fail determination circuit 5 performs the pass/fail determination based on the output of the comparison circuit 4 (Step S57). The determination result is inputted to the result analysis circuit 17 in the BIST circuit 1 through the flag register 6. Because in Step S55 and S56, the writing and reading operations are performed in the state where the failure is present in one of the bitlines of the memory 2 and the bit inversion circuit 14 inverts one bit of the output expected value, the read-out data does not coincide with the output expected value. Therefore, the pass/fail determination circuit 5 should output the value of “1” indicating that the failure bits are present in the memory 2. Accordingly, when the pass/fail determination circuit 5 outputs the value of “1” (Step S58), the result analysis circuit 17 determines that the function of the pass/fail determination works correctly (Step S60). On the other hand, if the pass/fail determination circuit 5 outputs the value of “0”, the result analysis circuit 17 determines that the function of the pass/fail determination does not work correctly (Step S59).

As mentioned above, the function verification of the pass/fail determination can be performed. If another circuit is provided in order to generate the output expected value assuming the state where the memory 2 fails, it is necessary to provide one more circuit whose circuit volume is comparable to that of the data generation circuit 12, thereby increasing the circuit volume. In the present embodiment, only by adding the bit inversion circuit 14, the BIST circuit 1 can generate the writing data and the expected value by setting one of the bitlines of the memory 2 to be in the failure state in appearance, thereby performing the function verification of the pass/fail determination while suppressing increase of the circuit volume.

Furthermore, the function verification of the repair analysis can be performed by using the BIST circuit 1 of FIG. 2.

In the present embodiment, the failure is not set in a specific address but is set in one of the bitlines of the memory 2. Therefore, the repair analysis of the present embodiment targets the repair processing for replacing all the memory cells connected to a specific bitline with the spare memory cells.

The function verification of the repair analysis according to the present embodiment is, for example, performed as described hereinafter. Firstly, the BIST circuit 1 performs writing to and reading from the memory 2 in the state where no failures are present. The repair analysis circuit 7 performs the repair analysis, and the obtained repair solution is outputted through the repair analysis circuit 7 to the outside test equipment. If the repair analysis circuit 7 outputs the repair solution indicating that it is unnecessary to perform repair, the test equipment determines that the function of the repair analysis works correctly.

Next, the BIST circuit 1 performs writing to and reading from the memory 2 in the state where the failure is present in one of the bitlines of the memory 2. The repair analysis circuit 7 outputs the repair solution to the test equipment 10. The test equipment 10 compares the repair solution with a prepared expected value of the repair solution to determine whether they coincide. When the repair solution coincides with the expected value of the repair solution, the test equipment 10 determines that the function of the repair analysis works correctly, and when does not coincide, the test equipment 10 determines that the function of the repair analysis does not work correctly.

The BIST circuit 1 may have the data generation circuit 12 which generates first data used for the function verification of the memory 2, the bit inversion circuit 14 (failure data generation circuit) which generates second data obtained by inverting a specific bit of the first data, and the timing register 13 (timing circuit) which adjusts timing of at least one of the first and the second data so that one of the first and the second data is used as a writing data to the memory 2 and the other of the first and the second data is used as an output expected value compared with the data read out from the memory 2. As an internal configuration of the BIST circuit 1, various modifications are conceivable.

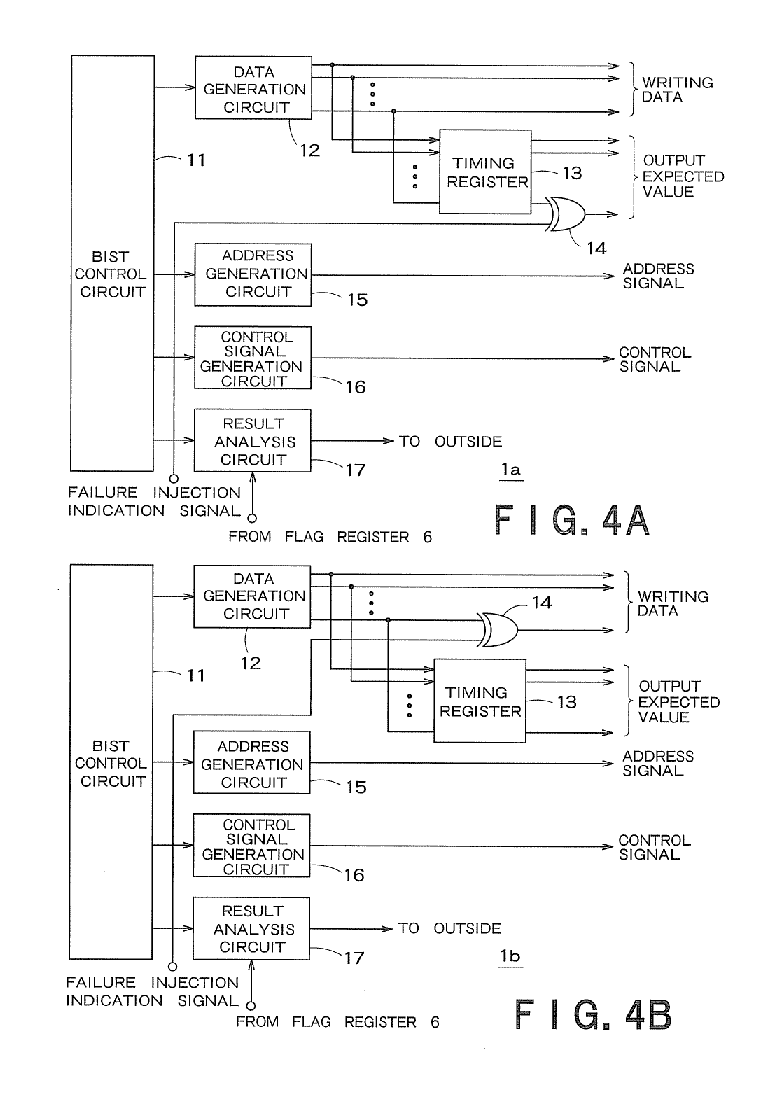

FIGS. 4(A) and 4(B) are block diagrams showing modification examples of the BIST circuit 1 of FIG. 2. In the BIST circuit 1 of FIG. 2, the first data is used as the writing data, and the second data is used as the output expected value after timing adjustment. Contrarily, in the BIST circuit 1a in FIG. 4(A), the first data is used as the writing data, and the second data generated by inverting one bit of the first data after timing adjustment is used as the output expected value. Furthermore, in the BIST circuit 1b of FIG. 4(B), the second data is used as the writing data, and the first data after timing adjustment is used as the output expected value.

In addition, the bit inversion circuit 14 can invert the read-out data from the memory 2, instead of inverting the writing data to the memory 2. The present embodiment assumes that one of the bitlines of the memory 2 is set to be in the failure state, and it is not limited which one of the bitlines is provided with the bit inversion circuit 14.

As described above, in the present embodiment, the bit inversion circuit 14 is provided in the BIST circuit 1 and inverts a part of the bits of the writing data based on the failure injection indication signal. Therefore, even if the memory 2 has no failure bits in practical, the failure bit can be injected to the memory 2 virtually, thereby performing the simplified function verification of the pass/fail determination and the repair analysis.

### Second Embodiment

In the first embodiment, the failure bit(s) of one bit of fixed bits is injected in the first embodiment. On the other hand, in a second embodiment, which will be explained below, the BIST circuit 1c can inject the failure bits to an arbitrary bit position.

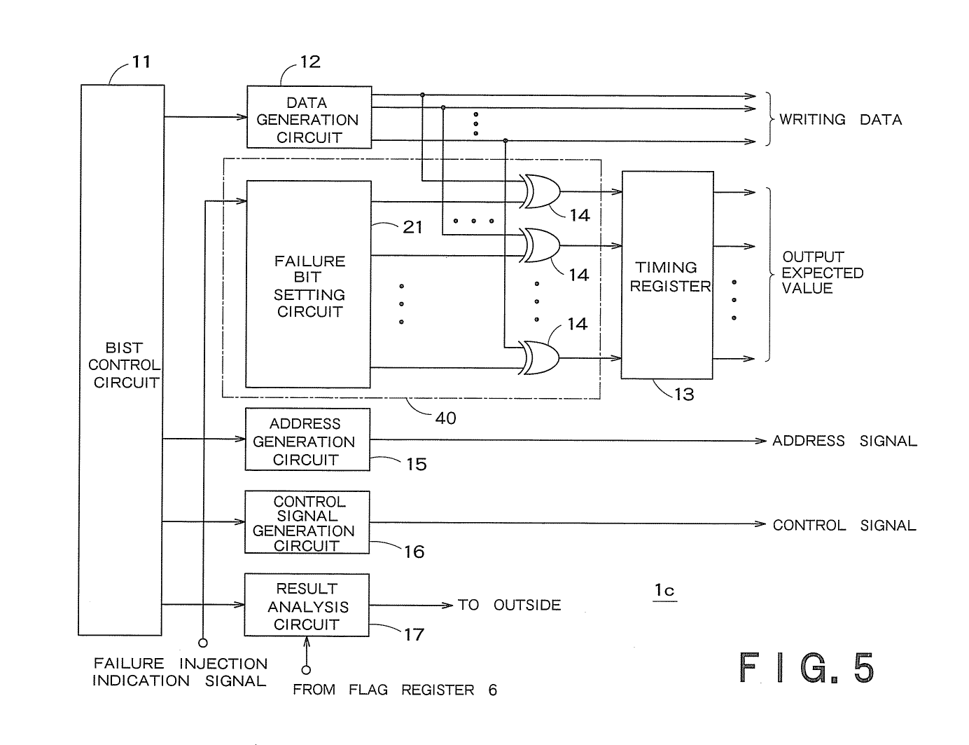

A schematic configuration of a semiconductor integrated circuit according to the second embodiment is the same as that of FIG. 1. However, an internal configuration of the BIST circuit 1c is different form that according the first embodiment. FIG. 5 is a block diagram showing an example of the internal configuration of the BIST circuit 1c according to the second embodiment of the present invention. In FIG. 5, components common to those of FIG. 2 have common reference numerals, respectively. Hereinafter, components different from FIG. 2 will be mainly described. The BIST circuit is of FIG. 5 has a failure data generation circuit 40 in addition to configurations of the BIST circuit 1 of FIG. 2.

The failure data generation circuit 40 has a failure bit setting circuit 21 and a plurality of bit inversion circuits 14 provided corresponding to each bit of the writing data. Note that the BIST circuit 1c of FIG. 5 can be modified in the same way as FIG. 4.

The failure bit setting circuit 21 generates a failure setting signal based on the failure injection indication signal. According to the failure setting signal, the bit inversion circuit 14 determines whether to perform a bit-inverting operation. That is, the failure bit setting circuit 21 can set the failure to any multiple bitlines at the same time.

If the BIST circuit 1c of FIG. 5 is used, it is possible to perform the function verification of the pass/fail determination in more detail than that of the first embodiment. That is, the failure bit setting circuit 21 controls the bit inversion circuit 14 so that each of the bitlines of the memory 2 is set to be in the failure state by turns, and the result analysis circuit 17 confirms the determination result of the pass/fail determination circuit 5 by each time when the failure state changes. By such a manner, it is possible to verify that the function verification of the pass/fail determination operates correctly, whichever of the bitlines is in the failure state.

Furthermore, more detailed function verification of the repair analysis can be performed by using the BIST circuit is of FIG. 5, which will be explained below.

In the repair analysis, the repair according to a location of the failure bit is performed. Therefore, the failure bit setting circuit 21 injects the failure bit to each bitline of the memory 2 selected by turns among all the bitlines, and the repair solution is outputted to the outside test equipment 10. The test equipment 10 confirms whether the repair solution coincides with a prepared expected value of the repair solution. By such a manner, it is possible to perform the function verification that the repair solution depending on the location of the failure bit is obtained.

Here, because the spare memory is finite, there are some failure patterns which cannot be repaired according to the number and the location of the failure bits. In this case, the repair analysis circuit 7 outputs the result indicating that it is impossible to repair. By setting the failure pattern for which the repair solution cannot be obtained by using the BIST circuit 1c, it is possible to perform the function verification regarding whether the repair analysis circuit 7 outputs the result indicating that it is impossible to repair when the memory 2 cannot be repaired.

Incidentally, the failure bit setting circuit 21 has a function of inverting each bit of the writing data by turns, as mentioned above. By using this function, it is possible to perform function verification of a Bit Write Enable (hereinafter, referred to as BWE) of the memory 2. Here, the function of the BWE means a function that even if the address and the writing data is inputted to the memory 2 and the control signal is set to write data to the memory 2, writing is not performed to only a bit specified by a BWE signal, which is explained below.

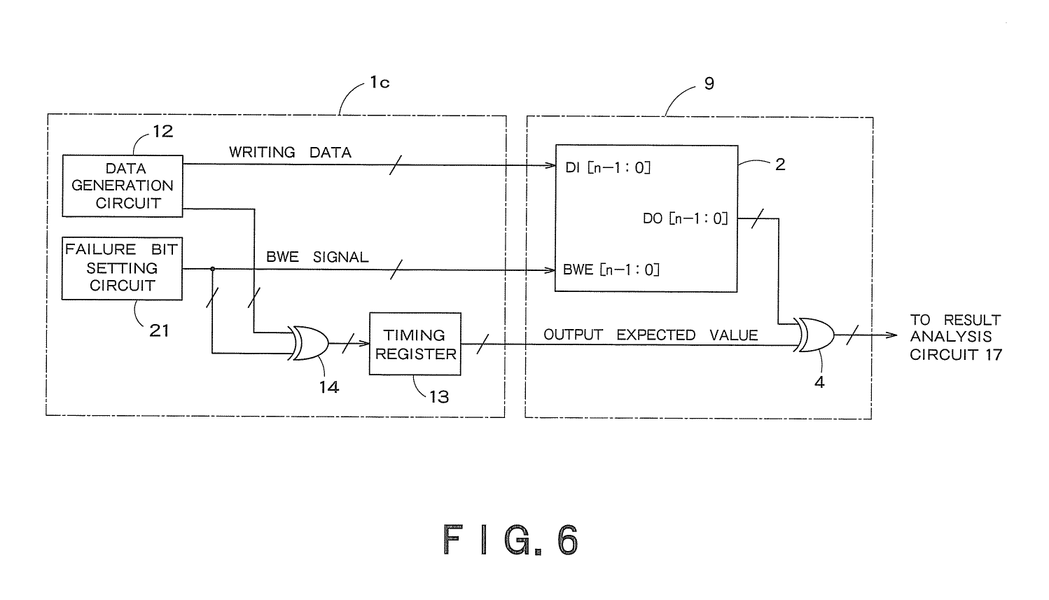

FIG. 6 is a block diagram showing a schematic configuration of a circuit for verifying the function of the BWE. The internal configuration of the BIST circuit 1c is the same as that of FIG. 5. The test circuit of FIG. 6 is different from that of FIG. 1 in technical features that the signal outputted from the failure bit setting circuit 21 in order to control the bit inversion circuit 14 is inputted to a BWE terminal of the memory 2 as the BWE signal, and that the output signals of the comparison circuit 4 are inputted to the result analysis circuit 17 in the BIST circuit 1c. However, it is unnecessary to add circuits for performing the function verification of the BWE. Here, other circuits and signals in the BIST circuit 1c and the memory collar 9 are omitted in FIG. 6.

In the following explanation, bit width of the input/output data of the memory 2 is assumed to be “n” bits and “n” pieces of the comparison circuits 4 and the bit inversion circuits 14 are provided, respectively.

Here, the BWE signal is a signal for controlling whether to perform writing to each of the bits of the memory 2. More specifically, the BWE signal is a signal of “n” bits which is the same as the bid width of the input/output data of the memory 2. When the “m”-th bit (0≦m≦n−1) of the BWE signal is the value of “0”, writing to the “m”-th bit is performed. On the other hand, when the “m”-th bit of the BWE signal is the value of “1”, writing to the “m”-th bit is not performed (i.e. writing is masked).

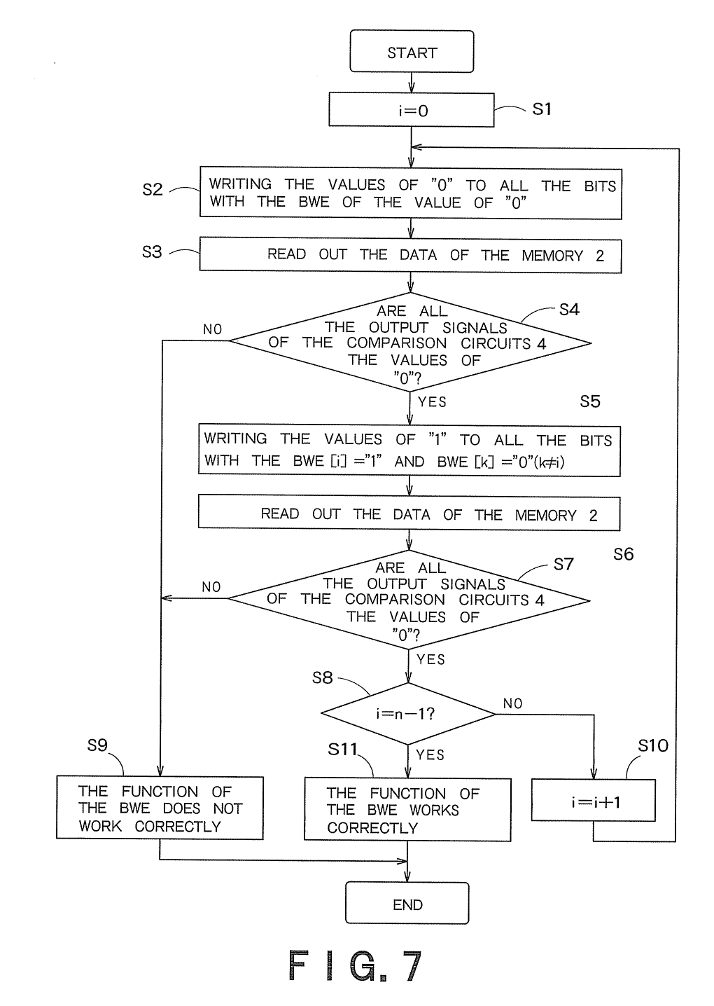

FIG. 7 is a flowchart showing a sequence of performing the function verification of the BWE using the test circuit of FIG. 6.

Here, when conducting the test, the address signal generated by the address generation circuit 15 can be a fixed value (e.g. address of “0”).

Firstly, the failure bit setting circuit 21 initializes the bit location i to be “0” (Step S1). Next, the failure bit setting circuit 21 sets all the bits of the BWE signal to be the values of “0”, and the BIST circuit is writes the values of “0” to all the bits of the memory 2 (Step S2). In this time, because the BWE signal, all bits of which are the values of “0”, is inputted to the bit inversion circuit 14, the bit inversion circuit 14 does not invert the output expected value and all the bits of the output expected value have the value of “0”. Furthermore, writing is not masked and the value of “0” is written to all the bits, respectively.

Then, the BIST circuit is reads out the data written in the memory 2 (Step S3). If the function of the BWE works correctly, the read-out data coincides with the output expected value because all the bits of the read-out data have the value of “0” and all the bits of the output expected value have also the value of “0”.

Therefore, all the comparison circuits 4 output the value of “0”. On the other hand, if the function of the BWE does not work correctly and a specific bit of the read-out data is the value of “1”, the comparison circuit 4 corresponding to the bit of the value of “1” outputs the value of “1”. As a result, when at least one bit of the outputs of the comparison circuits 4 has the value of “1”, the result analysis circuit 17 determines that the function of the BWE does not work correctly (Step S4 and S9).

Next, the failure bit setting circuit 21 sets the “i”-th bit of the BWE signal to be the value of “1” and the other bits of the BWE signal to be the value of “0”, and the BIST circuit 1c write the value of “1” to all the bits of the memory 2 (Step S5).

In this time, the “i”-th bit of the data of the memory 2 is not rewritten because writing is masked. Namely, the “i”-th bit of the memory 2 keeps the value of “0”, which is the value written in Step S2, and the value of “1” is written to the other bits of the memory 2.

Furthermore, the BWE signal, only the “i”-th bit of which is the value of “1”, is inputted to the bit inversion circuit 14, and the bit inversion circuit 14 inverts the “i”-th bit of the output expected value. That is, the “i”-th bit of the output expected value has the value of “0” and the other bits of the output expected value have the value of “1”.

After that, the BIST circuit 1c reads out the data written in the memory 2 (Step S6). If the function of the BWE works correctly, the “i”-th bit of the read-out data has the value of “0” and the other bits of the read-out data have the value of “1”. In this time, the read-out data coincides with the output expected value, and all the comparison circuits 4 output the value of “0”. On the other hand, if the function of the BWE does not work correctly, the read-out data does not coincide with the output expected value. Therefore, the comparison circuit 4 corresponding to the bit which does not coincide outputs the value of “1”. As a result, when at least one bit of the outputs of the comparison circuits 4 has the value of “1”, the result analysis circuit 17 determines that the function of the BWE does not work correctly (Step S7 and S9).

The above processing is performed for all the bits (i=“0” to “n−1”) (Step S8 and S10), and when it is not determined that the function of the BWE does not work correctly at Step S4 and S7, the result analysis circuit 17 determines that the function of the BWE works correctly (Step S11).

Note that in the test of FIG. 7, it is possible to perform the function verification that when the “i”-th bit of the BWE signal has the value of “1”, the “i”-th bit of the data is not rewritten from the value of “0” to the value of “1” among the functions of the BWE. However, it is impossible to perform the function verification that when the “i”-th bit of the BWE signal has the value of “1”, the “i”-th bit of the data is not rewritten from the value of “1” to the value of “0”. Therefore, it is preferable to perform the same processing as FIG. 7 by writing the values of “1” to all the bits at Step S2 and that writing the values of “0” to all the bits at Step S5 in addition to the test of FIG. 7. By such a manner, it is possible to perform the function verification that when the “i”-th bit of the BWE signal has the value of “1”, the data is not rewritten from the value of “1” to the value of “0”.

In the FIG. 6, the first data generated by the data generation circuit 12 is written in the memory 2 and the second data obtained by inverting one specific bit of the first data is used as the output expected value. However, the first data can be used as the output expected value, and the second data can be written in the memory 2. In this case, the circuit configuration of the comparison circuit 4 can be modified, if needed.

As described above, in the second embodiment, the bit inversion circuits 14 corresponding to all the bit of the writing data are provided in the BIST circuit 1c, and the failure bit setting circuit 21 inverts any bits of the output expected value. Therefore, even if the memory 2 has no failure bits in practical, the virtual failure bits can be simply injected to any bits. Because of this, more detailed function verification of the pass/fail determination and the repair analysis can be performed. Furthermore, the function verification of the BWE of the memory 2 can be performed by using the BIST circuit is for performing the pass/fail determination and the repair analysis without adding other circuit.

### Third Embodiment

The first and the second embodiments described above do not assume that the failure is set to a specific address in the memory 2, and the embodiments intends to set the bitline of the memory 2 to be in the failure state. On the other hand, a third embodiment, which will be explained hereinafter, sets a specific address in the memory 2 to be in the failure state.

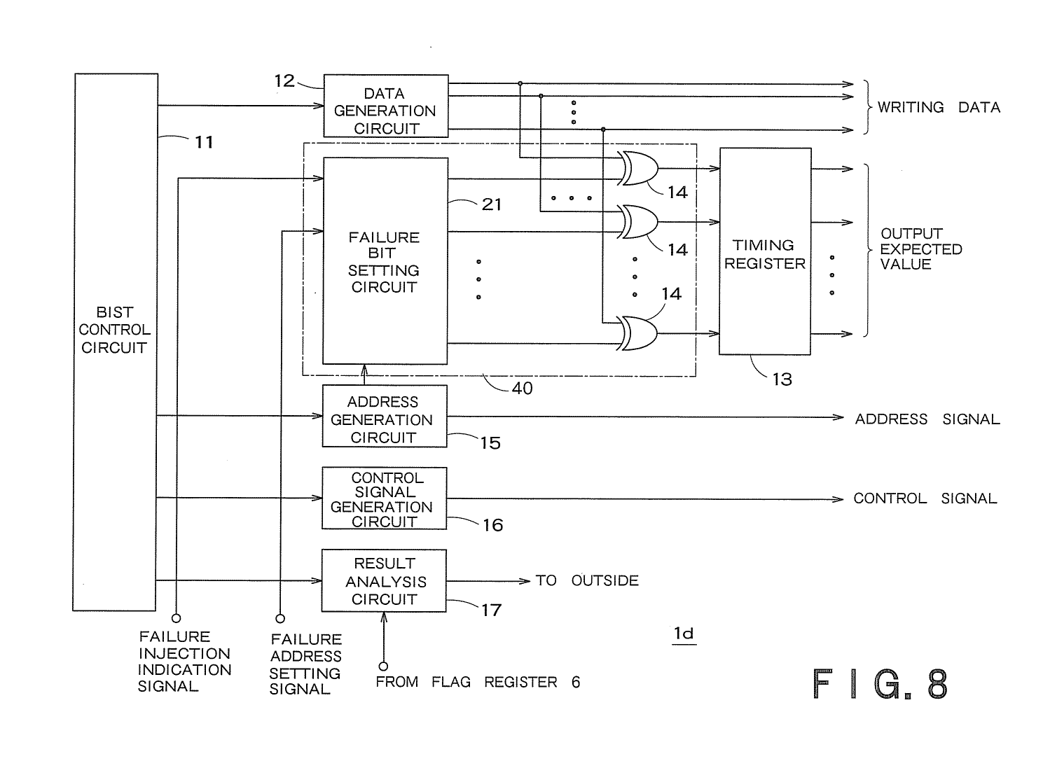

FIG. 8 is a block diagram showing an example of an internal configuration of the BIST circuit 1d according to the third embodiment of the present invention. In FIG. 8, components common to those of FIG. 5 have common reference numerals, respectively. Hereinafter, components different from FIG. 5 will be mainly described.

The BIST circuit 1d of FIG. 8 is different from that of FIG. 5 in a technical feature that the address signal is inputted from the address generation circuit 15 to the failure bit setting circuit 21.

Furthermore, not only the failure injection indication signal, but a failure address setting input signal are inputted to the failure bit setting circuit 21. The failure address setting input signal is a signal indicative of an address of the memory cell to which the failure is injected. The failure address setting input signal is inputted from a test mode control circuit (not shown) outside of the BIST circuit 1d, for example. Note that the BIST circuit 1d of FIG. 8 can be modified as FIG. 4.

When the address set by the failure address setting input signal coincides with the address signal generated by the address generation circuit 15, the failure bit setting circuit 21 controls the bit inversion circuit 14 to invert the writing data according to the failure injection indication signal, thereby injecting the failure bits. On the other hand, when both of the addresses do not coincide, the failure bit setting circuit 21 does not inject the failure bits. In this way, the BIST circuit 1d can indicate both of the address and the bit, thereby injecting the failure to a specific cell expressing a minimum unit of the memory 2.

By using the BIST circuit 1d of FIG. 8, it is possible to perform not only the function verification of the pass/fail determination and the repair analysis by each bitline of the memory 2, but the function verification of the pass/fail determination and the repair analysis of each cell in the memory 2. For example, in a case where one spare unit is provided corresponding to cell groups in an I/O index aligned in the direction of the addresses, even if there are failures in multiple cells corresponding to the same bit in different addresses respectively, the repair analysis circuit 7 can repair the memory 2. However, if there are failures in multiple cells corresponding to different bits in the same address respectively, the repair analysis circuit 7 cannot repair the memory 2.

By using the BIST circuit 1d of FIG. 8, it is possible to perform the function verification that when there are failures in multiple cells corresponding to the same bit in different addresses, the correct repair solution is outputted, and that when there are failures multiple cells corresponding to different bits in the same address, information indicating that the repair is impossible is outputted.

As described above, in the third embodiment, the verification of the pass/fail determination and the repair analysis can be performed by setting a specific cell to be in the failure state in units of a specific cell in the memory 2. Particularly, in the present embodiment, even if the memory 2 has no failure bits in practical, the virtual failure bits can be simply injected to any cells, thereby performing the function verification of the pass/fail determination and the repair analysis in more detail than the second embodiment.

### Fourth Embodiment

A fourth embodiment, which will be explained hereinafter, performs function verification of a repair operation of a memory.

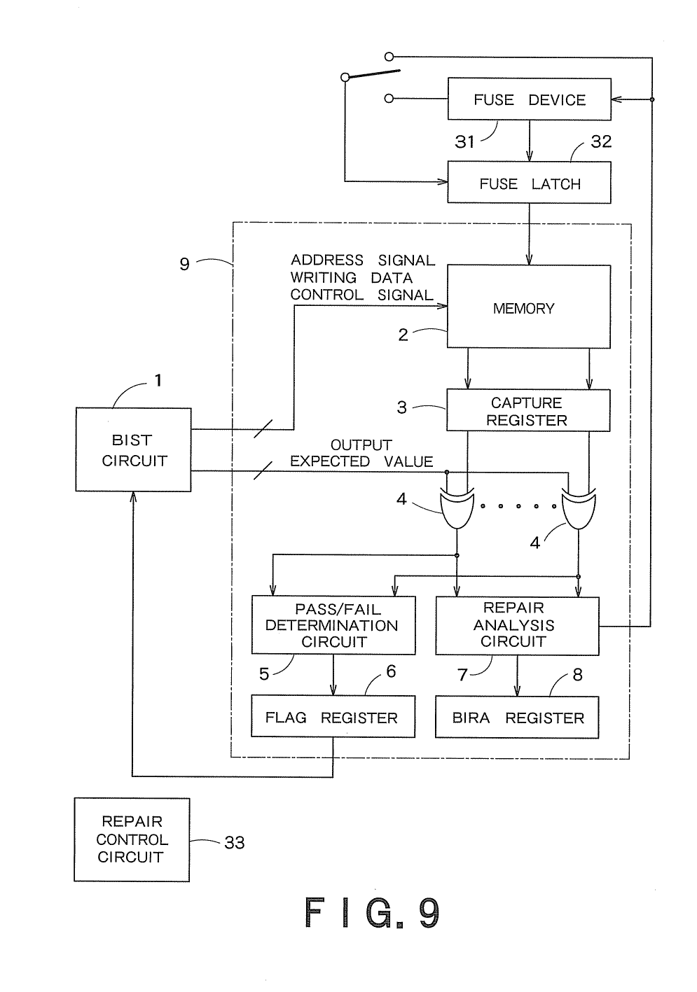

FIG. 9 is a schematic configuration of a semiconductor integrated circuit according to the fourth embodiment of the present invention. In FIG. 9, components common to those of FIG. 1 have common reference numerals, respectively. Hereinafter, components different from FIG. 1 will be mainly described. The semiconductor integrated circuit of FIG. 9 has a fuse device 31 (program circuit), a fuse latch (transfer circuit), and a repair control circuit 33 in addition to the components the semiconductor integrated device of FIG. 1. The repair control circuit 33 is, for example, integrated in the same chip in which the BIST circuit 1 is integrated. An internal configuration of the BIST circuit 1 can be one shown in one of the above embodiments. Note that signals for controlling the repair processing are omitted in FIG. 9.

The repair solution generated by the repair analysis circuit 7 is programmed in the fuse device 31. The fuse latch 32 transfers data programmed in the fuse device 31 to the memory 2. The data is used in order to replace the address for accessing the memory 2 with an address in the spare memory (redundancy part). Therefore, the memory 2 can be set to be in a state after repaired, i.e. a state where no failures are present in the memory 2 in appearance. An electric fuse which can be programmed by a test equipment (not shown) only once, for example, is used as the fuse device 31. Other programmable device such as a flash memory can be used instead of the fuse device 31.

The repair control circuit 33 controls each of the circuits in the BIST circuit 1 and the memory collar 9 in the repair analysis, thereby performing a built-in self repair (hereinafter, referred to as BISR) is performed.

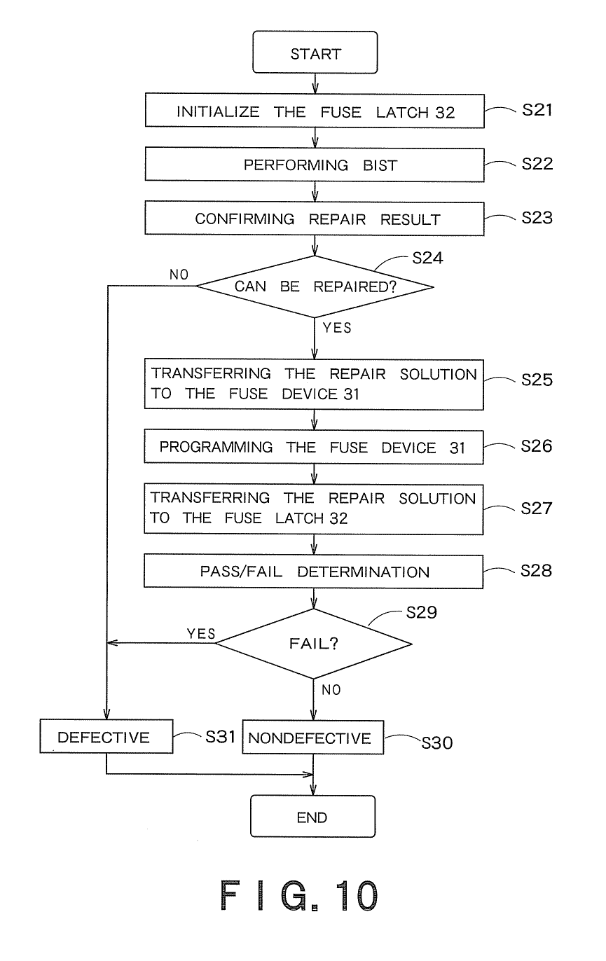

FIG. 10 is a flowchart showing a sequence of the repair processing of the memory 2. In the present embodiment, the function verification of the repair processing of FIG. 10 is performed without adding the other circuits to the circuit shown of FIG. 9. To begin with, the repair processing of the memory 2 will be explained with reference to FIG. 10.

Firstly, the repair control circuit 33 initializes the memory 2 (Step S21). More specifically, the repair control circuit 33 reads out contents of the fuse device 31 which has not been programmed yet to transfer the read-out data to the fuse latch 32 in serial or in parallel. By such a manner, the memory 2 is set to be a state before repaired. If the fuse latch 32 has a set or reset function, the repair control circuit 33 can set the memory 2 to be in the state before repaired with the reset function.

Secondly, the repair control circuit 33 controls the BIST circuit 1 to perform the pass/fail determination and the repair analysis of the memory 2 (Step S22). The pass/fail determination circuit 5 saves the presence/absence of the failure bits or the like in the flag register 6. Furthermore, when the memory 2 has the failure bit, the repair analysis circuit 7 performs the repair analysis based on the determination result of the pass/fail determination circuit 5 and saves the repair solution in the BIRA register 8 (Step S23). Here, if the repair analysis circuit 7 determines that the failure bits in the memory 2 cannot be repaired, the repair control circuit 33 determines that the memory 2 is defective (Step S31).

When the repair analysis circuit 7 determines that the failure bits in the memory 2 can be repaired, the repair control circuit 33 transfers the repair solution to the fuse device 31 (Step S25), and the fuse device 31 is programmed so that the memory 2 becomes the state after repaired (Step S26).

Next, the repair control circuit 33 reads out the content of the programmed fuse device 31 to transfer the read-out data to the fuse latch 32 (Step S27). Because of this, the memory 2 is set to be in the state after repaired.

After that, the repair control circuit 33 performs the pass/fail determination (Step S28). When the pass/fail determination circuit 5 determines that the memory 2 has no failure bits, the memory 2 is repaired and is determined to be a nondefective one (Step S30). On the other hand, when the pass/fail determination circuit 5 detects the failure bit in spite of setting the memory 2 to be in the state after repaired, it is considered that the repair analysis circuit 7 and/or the fuse device 31 or the like has some failures, and the repair control circuit 33 determines the memory 2 to be a defective one (Step S31).

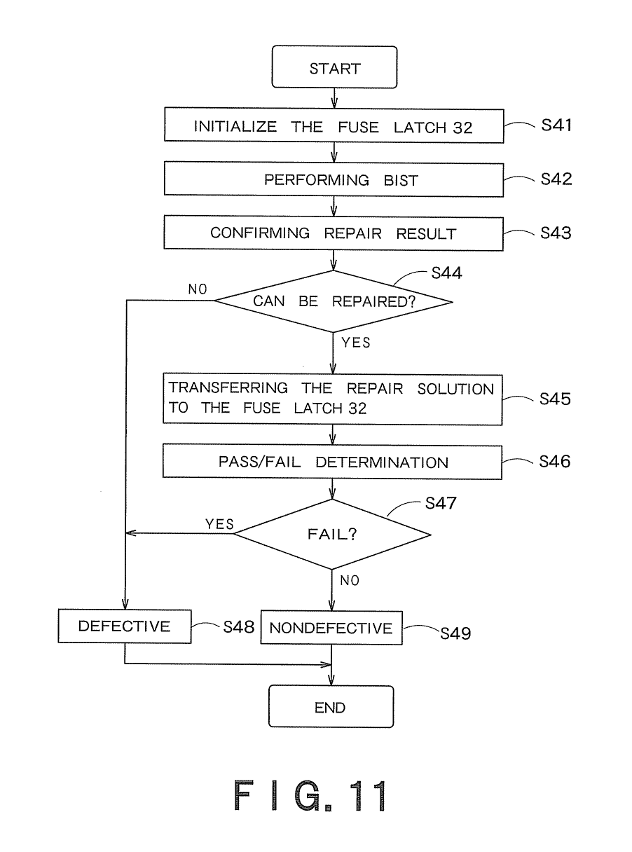

In the present embodiment, the function verification of the repair processing of FIG. 10 is performed using the configuration of FIG. 9. FIG. 11 is a flowchart showing a sequence of the function verification of the repair processing of FIG. 10.

Firstly, the memory 2 is initialized as well as Step S21 of FIG. 10 (Step S41). Secondly, the repair control circuit 33 controls the BIST circuit 1 to read out data written in the memory 2, and the comparison circuit 4 compares the read-out data with the output expected value. The pass/fail determination and the repair analysis of the memory 2 are performed based on the comparison result (Step S42). In this time, the BIST circuit 1 injects the failure bit which can be repaired to the writing data to the memory or to the output expected value. That is, the pass/fail determination and the repair analysis are performed in a state where at least one bit of the writing data to the memory 2 or the output expected value is inverted.

The pass/fail determination circuit 5 saves the presence/absence of the failure bits or the like in the flag register 6. The repair analysis circuit 7 performs the repair analysis and saves the repair solution in the BIRA register 8 (Step S43). In the case where the repair analysis circuit 7 determines that the failure bit in the memory 2 cannot be repaired in spite of setting the failure bit which can be repaired at Step S42, the case shows that there is a failure in the function of the repair analysis. Therefore, the repair control circuit 33 determines that the memory 2 to be a defective one (Step S48).

When the repair analysis circuit 7 determines that the failure bits in the memory 2 can be repaired with the spare memory, the repair control circuit 33 transfers the repair solution to the fuse device 31 (Step S45).

More specifically, the repair control circuit 33 sets a location in the spare memory to which the failure bit in the memory 2 is replaced. Different from FIG. 10, the BIST control circuit 11 does not transfer the repair solution to the fuse device 31. The reason is that the fuse device 31 is programmable only once, and therefore an actual failure bit in the memory 2 cannot be repaired any more if fuse device 31 is programmed in order to repair the failure bit for the verification set by the BIST circuit 1.

After that, the repair control circuit 33 performs the pass/fail determination (Step S46) to verify whether the replacement to the spare memory is performed correctly. In this time, the BIST circuit 1 generates the writing data or the like by setting the state where no failure bits are present. When the pass/fail determination circuit 5 determines that the memory 2 has no failure bits based on the result of the pass/fail determination, the repair control circuit 33 determines that the repair operation of FIG. 10 works correctly (Step S49). On the other hand, when the pass/fail determination circuit 5 detects the failure bit, the repair control circuit 33 determines that the memory 2 is a defective one (Step S48). In this case, it is considered that the repair of the memory 2 cannot be performed correctly on the ground that there are some problems in the repair control circuit 33, the fuse latch 32 and/or a transmission pass from the repair control circuit 33 to the fuse latch 32 or to the fuse device 31.

As described above, in the fourth embodiment, the function verification of the repair processing is performed using the BIST circuit 1 which can inject the failure bits. Therefore, even if the memory 2 has no failure bits in practical, the function verification of the repair operation of the memory can be performed using only the BIST circuit 1 for performing the pass/fail determination and the repair analysis without programming the fuse device 31.

Although based on above description, those skilled in the art can figure out additional effects and variations of the present invention, the aspect of the present invention is not limited to the stated each embodiments. Various additions, alterations and partial deletions can be done to the present invention within the conceptualistic thought and purpose of the present invention drawn on the claims and the equivalents.

1. A semiconductor integrated circuit comprising:
a data generation circuit configured to generate first data used for function verification of a built-in self test circuit and a built-in redundancy allocation circuit of a memory;
a failure data generation circuit configured to generate second data for conducting a built in self test by inverting at least one bit of the first data based on a failure injection indication signal; and
a timing circuit configured to adjust timing of at least one of the first and the second data in order to use one of the first and the second data as writing data to the memory and to use the other as an output expected value compared with data read out from the memory.

2. The circuit of claim 1, wherein the timing circuit adjusts a timing of at least one of the first and the second data in consideration of a time required for writing the writing data to the memory and a time required for reading out the written data from the memory.

3. The circuit of claim 1, wherein the failure data generation circuit comprises:
a bit inversion circuit configured to decide whether to invert the first data; and
a failure bit setting circuit configured to set whether the bit inversion circuit performs a bit inversion operation based on the failure injection indication signal.

4. The circuit of claim 3, wherein the first data and the second data have a plurality of bits, respectively,
a plurality of bit inversion circuits are provided corresponding to each bit of the first data, and
the failure bit setting circuit controls the plurality of bit inversion circuits to perform the bit inversion operation by turns.

5. The circuit of claim 3, further comprising an address generation circuit configured to generate an address signal for setting a location of the memory to write the first or the second data,
wherein a failure address setting input signal indicative of a specific address to inject failure data in the memory is inputted to the failure bit setting circuit, and
the failure bit setting circuit is configured to control the bit inversion circuits corresponding to the specific address to perform the bit inversion operation when the failure address setting input signal coincides with the address signal generated by the address generation circuit.

6. The circuit of claim 3, wherein the first data and the second data have a plurality of bits, respectively,
a plurality of bit inversion circuits are provided corresponding to each bit of the first data, and
the failure bit setting circuit generates a failure setting signal for setting whether each of the plurality of bit inversion circuits performs the bit inversion operation to based on the failure injection indication signal,
the plurality of bit inversion circuits decides whether to inverse a corresponding bit of the first data according to a value of each bit of the failure setting signal, and
the memory decides whether to perform a writing of the failure data according to the value of each bit of the failure setting signal in units of one bit.

7. The circuit of claim 6, wherein:
the memory has a BWE (Bit Write Enable) terminal of a plurality of bits, the BWE terminal being capable of deciding whether to write data by a unit of a bit, and
the failure setting signal is inputted to the BWE terminal of the memory.

8. The circuit of claim 7 further comprising a result analysis circuit configured to determine whether the BWE terminal of the memory works correctly using the failure setting signal.

9. A circuit function verification device comprising:
a data generation circuit configured to generate first data used for function verification of a built-in self test circuit and a built-in redundancy allocation circuit of a memory having a redundancy part;
a failure data generation circuit configured to generate second data for conducting a built in self test by inverting at least one bit of the first data based on a failure injection indication signal;
a timing circuit configured to adjust timing of at least one of the first and the second data in order to use one of the first and the second data as writing data to the memory and to use the other as an output expected value compared with data read out from the memory;
a comparison circuit configured to read out data written in the memory to compare the read-out data with the output expected value; and
a pass/fail determination circuit configured to determine whether at least one failure bit is present in the memory based on a comparison result of the comparison circuit.

10. The device of claim 9, wherein the timing circuit adjusts a timing of at least one of the first and the second data in consideration of a time required for writing the writing data to the memory and a time required for reading out the written data from the memory.

11. The device of claim 9 further comprising:
a repair analysis circuit configured to determine whether the failure bit can be repaired using the redundancy part based on the comparison result of the comparison circuit when at least one failure bit is present in the memory and to generate a repair solution indicative of a location in the redundancy part to replace the failure bit if the failure bit can be repaired; and
a test equipment configured to determine whether the repair analysis circuit works correctly by comparing the repair solution with an expected value of the repair solution generated in advance.

12. The device of claim 9, wherein the failure data generation circuit comprises:
a bit inversion circuit configured to decide whether to invert the first data; and
a failure bit setting circuit configured to set whether the bit inversion circuit performs a bit inversion operation based on the failure injection indication signal.

13. The device of claim 12, wherein the first data and the second data have a plurality of bits, respectively,
a plurality of bit inversion circuits are provided corresponding to each bit of the first data, and
the failure bit setting circuit controls the plurality of bit inversion circuits to perform the bit inversion operation by turns.

14. The device of claim 12 further comprising a address generation circuit configured to generate an address signal for setting a location of the memory to write the first or the second data,
wherein a failure address setting input signal indicative of a specific address to inject failure data in the memory is inputted to the failure bit setting circuit, and
the failure bit setting circuit is configured to control the bit inversion circuits corresponding to the specific address to perform the bit inversion operation when the failure address setting input signal coincides with the address signal generated by the address generation circuit.

15. The device of claim 9 further comprising:
a repair analysis circuit configured to determine whether the failure bit can be repaired using the redundancy part based on the comparison result of the comparison circuit when at least one failure bit is present in the memory and to generate a repair solution indicative of a location in the redundancy part to replace the failure bit if the failure bit can be repaired;
a programming circuit configured to program the repair solution in a memory device;
a transfer circuit configured to transfer the programmed repair solution to the memory; and
a repair control circuit configured to determine whether the repair solution is transferred to the memory correctly.

16. A method of verifying circuit function comprising:
generating first data used for function verification of a built-in self test circuit and a built-in redundancy allocation circuit of a memory having a redundancy part;
generating second data for conducting a built in self test by inverting at least one bit of the first data based on a failure injection indication signal by a failure data generation circuit;
adjusting timing of at least one of the first and the second data in order to use one of the first and the second data as writing data to the memory and to use the other as an output expected value compared with data read out from the memory;
reading out data written in the memory to compare the read-out data with the output expected value; and
determining whether at least one failure bit is present in the memory based on a comparison result.

17. The method of claim 16 further comprising:
determining whether the failure bit can be repaired using the redundancy part based on the comparison result when at least one failure bit is present in the memory;
generating a repair solution indicative of a location in the redundancy part to replace the failure bit if the failure bit can be repaired; and
determining whether a function of generating the repair solution works correctly by comparing the repair solution with an expected value of the repair solution generated in advance.

18. The method of claim 16, wherein the first and the second data have a plurality of bits, respectively, and
upon generating the second data, the second data is generated by inverting each of the plurality of bits by turns.

19. The method of claim 16 further comprising:
generating an address signal for setting a location of the memory to write the first or the second data, and
inputting a failure address setting input signal indicative of a specific address to inject failure data in the memory
wherein upon generating the second data, a bit corresponding to the specific address is inverted when the failure address setting input signal coincides with the address signal.

20. The method of claim 16 further comprising:
determining whether the failure bit can be repaired using the redundancy part based on the comparison result when at least one failure bit is present in the memory;
setting a location in the redundancy part for allocating the failure bit when the failure bit can be repaired; and
verifying whether a replacement to the redundancy part is performed correctly by writing to and reading from the memory.
